(19) United States
(12) Patent Application Publication
(10) Pub. No.: US 2024/0061296 A1
(43) Pub. Date: Feb. 22, 2024

(54) ARRAY SUBSTRATE, DISPLAY PANEL, AND DISPLAY TERMINAL

(71) Applicants: HUIZHOU CHINA STAR OPTOELECTRONICS DISPLAY CO., LTD., Huizhou (CN); TCL CHINA STAR OPTOELECTRONICS TECHNOLOGY CO., LTD., Shenzhen, Guangdong (CN)

(72) Inventor: Zhiming ZHAN, Huizhou (CN)

(21) Appl. No.: 17/618,561

(22) PCT Filed: Nov. 12, 2021
(86) PCT No.: PCT/CN2021/130433

§ 371 Date: Dec. 13, 2021

(30) Foreign Application Priority Data
Nov. 4, 2021 (CN) 202111301756.6

(51) Int. Cl. G02F 1/1362; G09G 3/36; H01L 27/12; G02F 1/1343

(52) U.S. Cl. CPC G02F 1/136286; G09G 3/3648; H01L 27/124; G02F 1/134318; G09G 2300/0842; G09G 2320/0209; G02F 1/1368

(57) ABSTRACT

An array substrate, a display panel, and a display terminal are provided. The array substrate includes a plurality of scan lines and a plurality of data lines intersecting with the plurality of scan lines. A plurality of pixel units are defined by the plurality of scan lines and the plurality of data lines. Each of the pixel units includes a common electrode layer. The array substrate further includes a plurality of shielding connection lines. In an extending direction of the data lines, the common electrode layers in two adjacent pixel units are electrically connected by one of the shielding connection lines.

### FIELD OF INVENTION

The present disclosure relates to the field of display technologies, and in particular, to an array substrate, a display panel, and a display terminal.

### BACKGROUND OF INVENTION

Due to many advantages, such as thin body, power saving, and no radiation, liquid crystal displays (LCDs) are widely applied, for example, applied to liquid crystal televisions, mobile phones, personal digital assistants (PDAs), digital cameras, computer screens, or notebook computer screens, and the LCDs dominate the field of panel displaying. The LCD includes an array substrate, a color film substrate, and a liquid crystal layer located between the array substrate and the color film substrate. The array substrate is provided with a plurality of common electrode layers (Com). The plurality of common electrode layers do not form a crosslinking network in plane, and the voltage of the common electrode layer is susceptible to coupling of a Data (data line) signal, which is one of direct causes of horizontal crosstalk in the displayed image.

To reduce crosstalk, a design of a common electrode layer network (Mesh Com) is proposed, which stabilizes the signal by constructing a common electrode layer network in the plane, to reduce the coupling of the Data signal to the voltage of the common electrode layer, thereby reducing horizontal crosstalk in the displayed image. Currently, a frequently used Mesh Com uses additionally arranged metal wires for connection. The metal wires and the data lines are arranged at the same layer, and signals of two adjacent common electrode layers are respectively electrically connected to two ends of a metal wire through via holes, so as to be connected longitudinally in the plane. In addition, the common electrode layers are inputted with the same signal out of the plane, so that the entire Mesh Com is a closed circuit. Compared with a structure in which no Mesh Com is formed in the plane, using the metal wires for connection can better stabilize the voltages of the common electrode layers. However, the arrangement of the additional metal wires leads to a reduction in the aperture ratio of the array substrate and a weak voltage stabilization capability. Therefore, it is necessary to overcome the defect.

### SUMMARY OF INVENTION

### Technical Problem

Embodiments of the present disclosure provide an array substrate, to resolve the technical problem that instability of a voltage of a common electrode layer of an array substrate in the prior art easily causes horizontal crosstalk in a displayed image, and arrangement of additional metal wires for connection leads to a reduction in the aperture ratio and a weak voltage stabilization capability.

### Technical Solution

The embodiments of the present disclosure provide an array substrate, including a plurality of scan lines and a plurality of data lines intersecting with the plurality of scan lines, wherein a plurality of pixel units are defined by the plurality of scan lines and the plurality of data lines; and each of the pixel units includes a common electrode layer; and wherein the array substrate further includes a plurality of shielding connection lines, wherein in an extending direction of the data lines, the common electrode layers in two adjacent pixel units are electrically connected by one of the shielding connection lines.

In the array substrate provided in the embodiments of the present disclosure, each of the pixel units includes a pixel electrode layer, and the shielding connection lines and the pixel electrode layers are arranged at the same layer.

In the array substrate provided in the embodiments of the present disclosure, the array substrate further includes a plurality of shielding voltage lines parallel to the plurality of data lines, wherein each of the shielding voltage lines is located between two adjacent pixel units; and wherein the plurality of shielding voltage lines and the shielding connection lines are arranged at the same layer, and two ends of one of the shielding connection lines are respectively electrically connected to two adjacent shielding voltage lines.

In the array substrate provided in the embodiments of the present disclosure, an electrical signal transmitted by the shielding voltage line is a constant-voltage direct-current signal, and the constant-voltage direct-current signal is greater than or equal to 6 volts and less than or equal to 8 volts.

In the array substrate provided in the embodiments of the present disclosure, one of the shielding connection lines includes a first connection line and a second connection line, the first connection line is parallel to the data lines, and the second connection line is parallel to the scan lines; and a first end of the first connection line is electrically connected to one of the common electrode layers through a first via hole, and a second end of the first connection line is electrically connected to a first end of the second connection line; and a second end of the second connection line is electrically connected to another one of the common electrode layers through a second via hole.

In the array substrate provided in the embodiments of the present disclosure, each of the common electrode layers includes a first contact terminal and a second contact terminal, and the common electrode layer is electrically connected to the shielding connection lines on two sides of the common electrode layer respectively by using the first contact terminal and the second contact terminal, wherein in the same common electrode layer, the first contact terminal and the second contact terminal are arranged along diagonals of the common electrode layer or arranged along the extending direction of the data lines.

In the array substrate provided in the embodiments of the present disclosure, in a direction of a top view of the array substrate, an orthographic projection of one of the pixel electrode layers is located within an orthographic projection of one of the common electrode layers; and the common electrode layers and the scan lines are arranged at the same layer.

In the array substrate provided in the embodiments of the present disclosure, in the same pixel unit, a storage capacitor is formed between the common electrode layer and the pixel electrode layer.

The embodiments of the present disclosure provide a display panel, including an array substrate and a color film substrate, wherein the color film substrate and the array substrate are arranged opposite to each other, the array substrate includes a plurality of scan lines and a plurality of data lines intersecting with the plurality of scan lines, wherein a plurality of pixel units are defined by the plurality of scan lines and the plurality of data lines; and each of the pixel units includes a common electrode layer; and wherein the array substrate further includes a plurality of shielding connection lines, wherein in an extending direction of the data lines, the common electrode layers in two adjacent pixel units are electrically connected by one of the shielding connection lines.

In the display panel provided in the embodiments of the present disclosure, each of the pixel units includes a pixel electrode layer, and the shielding connection lines and the pixel electrode layers are arranged at the same layer.

In the display panel provided in the embodiments of the present disclosure, the array substrate further includes a plurality of shielding voltage lines parallel to the plurality of data lines, wherein each of the shielding voltage lines is located between two adjacent pixel units; and wherein the plurality of shielding voltage lines and the shielding connection lines are arranged at the same layer, and two ends of one of the shielding connection lines are respectively electrically connected to two adjacent shielding voltage lines.

In the display panel provided in the embodiments of the present disclosure, an electrical signal transmitted by the shielding voltage line is a constant-voltage direct-current signal, and the constant-voltage direct-current signal is greater than or equal to 6 volts and less than or equal to 8 volts.

In the display panel provided in the embodiments of the present disclosure, one of the shielding connection lines includes a first connection line and a second connection line, the first connection line is parallel to the data lines, and the second connection line is parallel to the scan lines; and a first end of the first connection line is electrically connected to one of the common electrode layers through a first via hole, and a second end of the first connection line is electrically connected to a first end of the second connection line; and a second end of the second connection line is electrically connected to another one of the common electrode layers through a second via hole.

In the display panel provided in the embodiments of the present disclosure, each of the common electrode layers includes a first contact terminal and a second contact terminal, and the common electrode layer is electrically connected to the shielding connection lines on two sides of the common electrode layer respectively by using the first contact terminal and the second contact terminal, wherein in the same common electrode layer, the first contact terminal and the second contact terminal are arranged along diagonals of the common electrode layer or arranged along the extending direction of the data lines.

In the display panel provided in the embodiments of the present disclosure, in a direction of a top view of the array substrate, an orthographic projection of one of the pixel electrode layers is located within an orthographic projection of one of the common electrode layers; and the common electrode layers and the scan lines are arranged at the same layer.

In the display panel provided in the embodiments of the present disclosure, in the same pixel unit, a storage capacitor is formed between the common electrode layer and the pixel electrode layer.

The embodiments of the present disclosure further provide a display terminal, including a terminal body and a display panel, wherein the terminal body and the display panel are combined into a whole, and the display panel includes an array substrate and a color film substrate, wherein the color film substrate and the array substrate are arranged opposite to each other, and the array substrate includes a plurality of scan lines and a plurality of data lines intersecting with the plurality of scan lines, wherein a plurality of pixel units are defined by the plurality of scan lines and the plurality of data lines; and each of the pixel units includes a common electrode layer; and wherein the array substrate further includes a plurality of shielding connection lines, wherein in an extending direction of the data lines, the common electrode layers in two adjacent pixel units are electrically connected by one of the shielding connection lines.

In the display terminal provided in the embodiments of the present disclosure, each of the pixel units includes a pixel electrode layer, and the shielding connection lines and the pixel electrode layers are arranged at the same layer.

In the display terminal provided in the embodiments of the present disclosure, the array substrate further includes a plurality of shielding voltage lines parallel to the plurality of data lines, wherein each of the shielding voltage lines is located between two adjacent pixel units; and wherein the plurality of shielding voltage lines and the shielding connection lines are arranged at the same layer, and two ends of one of the shielding connection lines are respectively electrically connected to two adjacent shielding voltage lines.

In the display terminal provided in the embodiments of the present disclosure, an electrical signal transmitted by the shielding voltage line is a constant-voltage direct-current signal, and the constant-voltage direct-current signal is greater than or equal to 6 volts and less than or equal to 8 volts.

### Beneficial Effects

An array substrate provided in the embodiments of the present disclosure includes a plurality of scan lines and a plurality of data lines intersecting with the plurality of scan lines, wherein a plurality of pixel units are defined by the plurality of scan lines and the plurality of data lines; and each of the pixel units includes a common electrode layer; and wherein the array substrate further includes a plurality of shielding connection lines, wherein in an extending direction of the data lines, the common electrode layers in two adjacent pixel units are electrically connected by one of the shielding connection lines. According to the present disclosure, adjacent common electrode layers are electrically connected by a shielding connection line, to form a crosslinking network of the common electrode layers, and voltages of the common electrode layers are equal to a voltage on the shielding connection line, which can further stabilize the voltages of the common electrode layers and reduce horizontal crosstalk without arrangement of additional metal wires, and causes no reduction in the aperture ratio.

### BRIEF DESCRIPTION OF DRAWINGS

To describe the technical solutions in the embodiments of the present disclosure more clearly, the following briefly describes the accompanying drawings required for describing the embodiments.

FIG. 1 is a schematic diagram of a basic structure of an array substrate according to an embodiment of the present disclosure.

FIG. 2 is an enlarged diagram of a location A in FIG. 1.

FIG. 3 is a schematic diagram of a film layer structure of a portion B in FIG. 2.

FIG. 4 is a schematic diagram of a basic structure of another array substrate according to an embodiment of the present disclosure.

FIG. 5 is a schematic diagram of a basic structure of still another array substrate according to an embodiment of the present disclosure.

### DETAILED DESCRIPTION OF PREFERRED EMBODIMENTS

The technical solutions of the embodiments of the present disclosure are clearly and completely described below with reference to the accompanying drawings of the embodiments of the present disclosure. In the accompanying drawings, for clarity and ease of understanding and description, sizes and thicknesses of components depicted in the accompanying drawings are not drawn to scale.

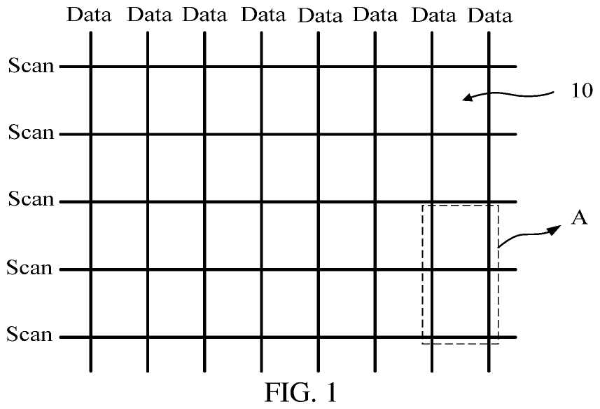

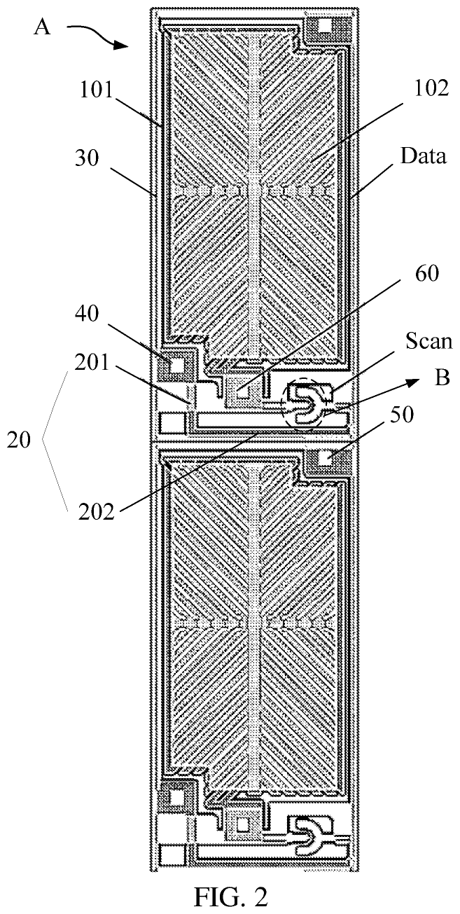

FIG. 1 is a schematic diagram of a basic structure of an array substrate according to an embodiment of the present disclosure. FIG. 2 is an enlarged diagram of a location A in FIG. 1. The array substrate includes a plurality of scan lines Scan and a plurality of data lines Data intersecting with the plurality of scan lines Scan, wherein a plurality of pixel units 10 are defined by the plurality of scan lines Scan and the plurality of data lines Data; and each of the pixel units 10 includes a common electrode layer 101; and wherein the array substrate further includes a plurality of shielding connection lines 20, wherein in an extending direction of the data lines Data, the common electrode layers 101 in two adjacent pixel units 10 are electrically connected by one of the shielding connection lines 20.

It may be understood that a plurality of common electrode layers 101 on a side of the array substrate are arranged separately, and a voltage of a single common electrode layer 101 is susceptible to coupling of a data line Data, and is instable, which easily causes horizontal crosstalk in a displayed image. Using additionally arranged metal lines to connect the plurality of common electrode layers 101 leads to a reduction in the aperture ratio of the array substrate and a weak voltage stabilization capability. According to the present disclosure, adjacent common electrode layers 101 are electrically connected by a shielding connection line 20, to form a crosslinking network of the common electrode layers 101, and voltages of the common electrode layers 101 are equal to a voltage on the shielding connection line 20, which can further stabilize the voltages of the common electrode layers 101 and reduce horizontal crosstalk without arrangement of additional metal wires, and causes no reduction in the aperture ratio.

In an embodiment, each of the pixel units 10 includes a pixel electrode layer 102, and the shielding connection lines 20 and the pixel electrode layers 102 are arranged at the same layer. It should be noted that the shielding connection lines 20 provided in the embodiments of the present disclosure are manufactured by using a transparent conductive material, and the shielding connection lines 20 and the pixel electrode layers 102 may be manufactured through the same process, thereby requiring no additional process steps and production costs.

In an embodiment, the pixel electrode layer 102 has a four-domain pixel electrode structure, including a main electrode and a branch electrode, wherein the main electrode and the branch electrode are combined into a shape obtained by superposing an “X” on a “+”. In other embodiments, the pixel electrode layer 102 may alternatively has an eight-domain pixel electrode structure or another frequently used electrode structure.

In an embodiment, the array substrate further includes a plurality of shielding voltage lines 30 parallel to the plurality of data lines Data, wherein each of the shielding voltage lines 30 is located between two adjacent pixel units 10; and wherein the plurality of shielding voltage lines 30 and the shielding connection lines 20 are arranged at the same layer, and two ends of one of the shielding connection lines 20 are respectively electrically connected to two adjacent shielding voltage lines 30. It should be noted that the shielding voltage lines 30 are configured to shield voltages of the data lines Data, to prevent voltage changes of the data lines Data from interfering the pixel electrode layers 102. In the present embodiment, in a direction of a top view of the array substrate, the shielding voltage line 30 is located between the data line Data and the pixel electrode layer 102. In other embodiments, in a direction of a top view of the array substrate, the shielding voltage line 30 overlaps the data line Data, which can shorten a distance between two pixel units 10 and improve resolution of the array substrate.

In an embodiment, an electrical signal transmitted by the shielding voltage line 30 is a constant-voltage direct-current signal, and the constant-voltage direct-current signal is greater than or equal to 6 volts and less than or equal to 8 volts. It may be understood that two ends of one of the shielding connection lines 20 are respectively electrically connected to two adjacent shielding voltage lines 30, that is, a voltage value on the shielding connection line 20 is equal to voltage values on the shielding voltage lines 30. The plurality of common electrode layers 101 are electrically connected by the shielding connection lines 20, that is, voltage values on the plurality of common electrode layers 101 are also constant-voltage direct-current signals ranging from 6 volts to 8 volts. Compared with the previous structure in which the common electrode layers 101 are arranged separately or metal wires are additionally arranged for connection, a voltage value obtained through electrical connection by using the shielding connection lines 20 is more stable, and is insusceptible to interference of the data lines Data.

In an embodiment, one of the shielding connection lines 20 includes a first connection line 201 and a second connection line 202, the first connection line 201 is parallel to the data lines Data, and the second connection line 202 is parallel to the scan lines Scan; and a first end of the first connection line 201 is electrically connected to one of the common electrode layers 101 through a first via hole 40, and a second end of the first connection line 201 is electrically connected to a first end of the second connection line 202; and a second end of the second connection line 202 is electrically connected to another one of the common electrode layers 101 through a second via hole 50. It may be understood that an electrical signal of the common electrode layer 101 in the upper part of FIG. 2 is transmitted to the first end of the first connection line 201 through the first via hole 40, subsequently transmitted to the second via hole 50 through the second end of the second connection line 202, and then transmitted to the common electrode layer 101 in the lower part through the second via hole 50, to implement longitudinal connection of a plurality of common electrode layers 101 in the plane. Because common electrode layers 101 out of the plane are inputted with the same signal, a crosslinking network of the common electrode layers 101 can be formed.

In an embodiment, in a direction of a top view of the array substrate, the second connection line 202 overlaps the scan line Scan, which can shorten a distance between two pixel units 10 and improve resolution of the array substrate.

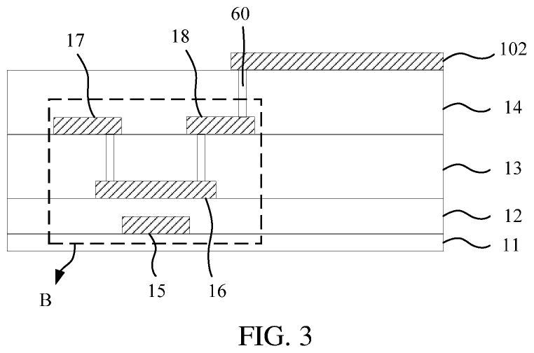

In an embodiment, the array substrate further includes a thin film transistor B. FIG. 3 is a schematic diagram of a film layer structure of a portion B in FIG. 2. The thin film transistor B includes a gate layer 15, a gate insulating layer 12, an active layer 16, an interlayer insulating layer 13, a source layer 17, and a drain layer 18. The gate layer 15 is located on a substrate layer 11; the gate insulating layer 12 is located on the gate layer 15 (wherein a description is made by using a bottom gate structure as an example in the present embodiment, and in other embodiments, a top gate structure may alternatively be used); the active layer 16 is located on the gate insulating layer 12; the interlayer insulating layer 13 is located on the active layer 16; the source layer 17 and the drain layer 18 are located on the interlayer insulating layer 13, and are electrically connected to two ends of the active layer 16 respectively through contact holes; a planarization layer 14 is located on the source layer 17 and the drain layer 18; and the pixel electrode layer 102 is electrically connected to the drain layer 18 through a third via hole 60.

Specifically, with reference to FIG. 2 and FIG. 3, the gate layer 15 of the thin film transistor B is electrically connected to the scan line Scan, and the source layer 17 of the thin film transistor B is electrically connected to the data line Data. When the scan line Scan controls a voltage of the gate layer 15 to turn on the thin film transistor B, an electrical signal on the data line Data enters the pixel electrode layer 102 through the thin film transistor B and the third via hole 60, and an electric field is formed between the pixel electrode layer 102 and a common electrode on the color film substrate, to control a deflection angle of liquid crystal.

In an embodiment, in a direction of a top view of the array substrate, the second connection line 202 overlaps the thin film transistor B, which can shorten a distance between two pixel units 10 and improve resolution of the array substrate.

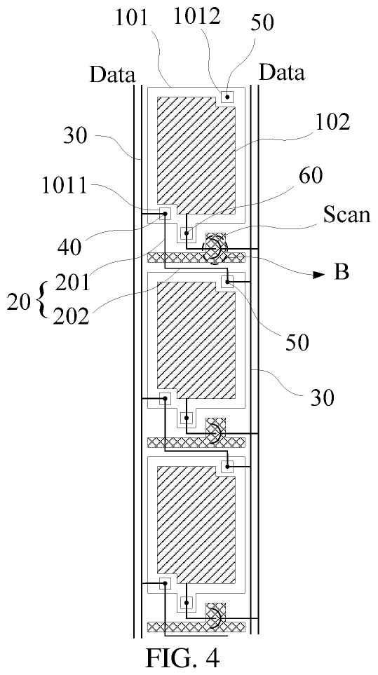

Subsequently, FIG. 4 is a schematic diagram of a basic structure of another array substrate according to an embodiment of the present disclosure. The array substrate includes a plurality of scan lines Scan and a plurality of data lines Data intersecting with the plurality of scan lines Scan, wherein a plurality of pixel units 10 are defined by the plurality of scan lines Scan and the plurality of data lines Data (shown in FIG. 1); and each of the pixel units 10 includes a common electrode layer 101; and wherein the array substrate further includes a plurality of shielding connection lines 20, wherein in an extending direction of the data lines Data, the common electrode layers 101 in two adjacent pixel units 10 are electrically connected by one of the shielding connection lines 20.

In the present embodiment, each of the common electrode layers 101 includes a first contact terminal 1011 and a second contact terminal 1012, and the common electrode layer 101 is electrically connected to the shielding connection lines 20 on two sides of the common electrode layer 101 respectively by using the first contact terminal 1011 and the second contact terminal 1012; and wherein in the same common electrode layer 101, the first contact terminal 1011 and the second contact terminal 1012 are arranged along diagonals of the common electrode layer 101 (shown in FIG. 4), so that electric fields of pixel electrode layers 102 are more evenly distributed.

It should be noted that first contact terminals 1011 and second contact terminals 1012 on two adjacent common electrode layers 101 are diagonally arranged, so that two ends of the shielding connection line 20 are respectively electrically connected to the shielding voltage lines 30 on two sides.

In an embodiment, in a direction of a top view of the array substrate, an orthographic projection of one of the pixel electrode layers 102 is located within an orthographic projection of one of the common electrode layers 101; and the common electrode layers 101 and the scan lines Scan are arranged at the same layer. It may be understood that the arrangement manner in the present embodiment can increase an overlapping area between the pixel electrode layer 102 and the common electrode layer 101.

In an embodiment, in the same pixel unit 10, a storage capacitor is formed between the common electrode layer 101 and the pixel electrode layer 102. When the scan line Scan controls a thin film transistor B to be turned on, the data line Data charges the pixel electrode layer 102 by using the thin film transistor B, and the charged charge is stored in the storage capacitor formed between the common electrode layer 101 and the pixel electrode layer 102. A larger overlapping area indicates a greater amount of stored charge.

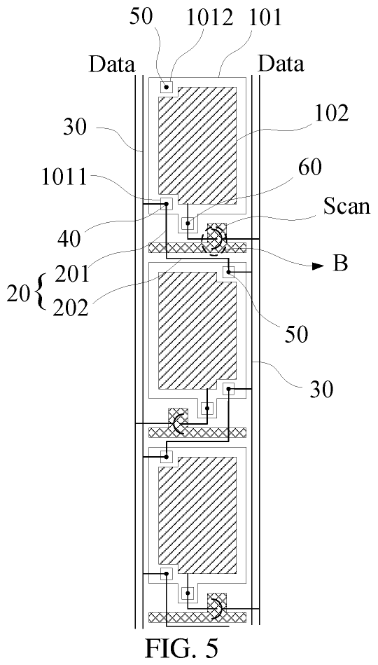

Subsequently, FIG. 5 is a schematic diagram of a basic structure of still another array substrate according to an embodiment of the present disclosure. The array substrate includes a plurality of scan lines Scan and a plurality of data lines Data intersecting with the plurality of scan lines Scan, wherein a plurality of pixel units 10 are defined by the plurality of scan lines Scan and the plurality of data lines Data (shown in FIG. 1); and each of the pixel units 10 includes a common electrode layer 101; and wherein the array substrate further includes a plurality of shielding connection lines 20, wherein in an extending direction of the data lines Data, the common electrode layers 101 in two adjacent pixel units 10 are electrically connected by one of the shielding connection lines 20.

In the present embodiment, each of the common electrode layers 101 includes a first contact terminal 1011 and a second contact terminal 1012, and the common electrode layer 101 is electrically connected to the shielding connection lines 20 on two sides of the common electrode layer 101 respectively by using the first contact terminal 1011 and the second contact terminal 1012; and wherein in the same common electrode layer 101, the first contact terminal 1011 and the second contact terminal 1012 are arranged along the extending direction of the data lines Data. It may be understood that in the same common electrode layer 101, both the first contact terminal 1011 and the second contact terminal 1012 are arranged on the left side or right side of the common electrode layer 101, and are alternately arranged on the left side or right side. Specifically, arranging the two contact terminals in the same common electrode layer 101 on the same side can facilitate the drilling process to make a first via hole 40 and a second via hole 50.

It should be noted that first contact terminals 1011 and second contact terminals 1012 on two adjacent common electrode layers 101 are diagonally arranged, so that two ends of the shielding connection line 20 are respectively electrically connected to the shielding voltage lines 30 on two sides.

The embodiments of the present disclosure provide a display panel, including the array substrate and the color film substrate described above, wherein the color film substrate and the array substrate are arranged opposite to each other. For a detailed structure of the array substrate, reference may be made to FIGS. 1 to 5 and related descriptions. Details are not described herein again.

In an embodiment, the color film substrate is provided with a common electrode, and a voltage of the common electrode is equal to a voltage on the shielding voltage line 30, to prevent a region other than the pixel electrode layer 102 (non-light-emitting region) from generating an electric field, and avoid deflection of liquid crystal of the non-light-emitting region, thereby achieving the light-shielding effect of the non-light-emitting region.

The embodiments of the present disclosure further provide a display terminal, including a terminal body and the display panel described above, wherein the terminal body and the display panel are combined into a whole. The display terminal provided in the embodiments of the present disclosure may be a product or component that has a display function, such as a mobile phone, a tablet computer, a notebook computer, a digital camera, or a navigator.

Based on the above, an array substrate provided in the embodiments of the present disclosure includes a plurality of scan lines and a plurality of data lines intersecting with the plurality of scan lines, wherein a plurality of pixel units are defined by the plurality of scan lines and the plurality of data lines; and each of the pixel units includes a common electrode layer; and wherein the array substrate further includes a plurality of shielding connection lines, wherein in an extending direction of the data lines, the common electrode layers in two adjacent pixel units are electrically connected by one of the shielding connection lines. According to the present disclosure, adjacent common electrode layers are electrically connected by a shielding connection line, to form a crosslinking network of the common electrode layers, and voltages of the common electrode layers are equal to a voltage on the shielding connection line, which can further stabilize the voltages of the common electrode layers and reduce horizontal crosstalk without arrangement of additional metal wires, and causes no reduction in the aperture ratio. Therefore, the technical problem that instability of a voltage of a common electrode layer of an array substrate in the prior art easily causes horizontal crosstalk in a displayed image, and arrangement of additional metal wires for connection leads to a reduction in the aperture ratio and a weak voltage stabilization capability.

The array substrate, the display panel, and the display terminal provided in the embodiments of the present disclosure are described above in detail. It should be understood that exemplary implementation described in this specification should be considered as merely descriptive, and are used to facilitate understanding of the method and the core idea of the present disclosure, but not intended to limit the present disclosure.

What is claimed is:

1. An array substrate, comprising a plurality of scan lines and a plurality of data lines intersecting with the plurality of scan lines, wherein a plurality of pixel units are defined by the plurality of scan lines and the plurality of data lines; and each of the pixel units comprises a common electrode layer; and wherein
the array substrate further comprises a plurality of shielding connection lines, wherein in an extending direction of the data lines, the common electrode layers in two adjacent pixel units are electrically connected by one of the shielding connection lines.

2. The array substrate as claimed in claim 1, wherein each of the pixel units comprises a pixel electrode layer, and the shielding connection lines and the pixel electrode layers are arranged at the same layer.

3. The array substrate as claimed in claim 2, further comprising a plurality of shielding voltage lines parallel to the plurality of data lines, wherein each of the shielding voltage lines is located between two adjacent pixel units; and wherein
the plurality of shielding voltage lines and the shielding connection lines are arranged at the same layer, and two ends of one of the shielding connection lines are respectively electrically connected to two adjacent shielding voltage lines.

4. The array substrate as claimed in claim 3, wherein an electrical signal transmitted by the shielding voltage line is a constant-voltage direct-current signal, and the constant-voltage direct-current signal is greater than or equal to 6 volts and less than or equal to 8 volts.

5. The array substrate as claimed in claim 2, wherein one of the shielding connection lines comprises a first connection line and a second connection line, the first connection line is parallel to the data lines, and the second connection line is parallel to the scan lines; and
a first end of the first connection line is electrically connected to one of the common electrode layers through a first via hole, and a second end of the first connection line is electrically connected to a first end of the second connection line; and a second end of the second connection line is electrically connected to another one of the common electrode layers through a second via hole.

6. The array substrate as claimed in claim 2, wherein each of the common electrode layers comprises a first contact terminal and a second contact terminal, and the common electrode layer is electrically connected to the shielding connection lines on two sides of the common electrode layer respectively by the first contact terminal and the second contact terminal, wherein in the same common electrode layer, the first contact terminal and the second contact terminal are arranged along diagonals of the common electrode layer or arranged along the extending direction of the data lines.

7. The array substrate as claimed in claim 2, wherein in a direction of a top view of the array substrate, an orthographic projection of one of the pixel electrode layers is located within an orthographic projection of one of the common electrode layers; and the common electrode layers and the scan lines are arranged at the same layer.

8. The array substrate as claimed in claim 2, wherein in the same pixel unit, a storage capacitor is formed between the common electrode layer and the pixel electrode layer.

9. A display panel, comprising an array substrate and a color film substrate, wherein the color film substrate and the array substrate are arranged opposite to each other, the array substrate comprises a plurality of scan lines and a plurality of data lines intersecting with the plurality of scan lines, wherein a plurality of pixel units are defined by the plurality of scan lines and the plurality of data lines; and each of the pixel units comprises a common electrode layer; and wherein the array substrate further comprises a plurality of shielding connection lines, wherein in an extending direction of the data lines, the common electrode layers in two adjacent pixel units are electrically connected by one of the shielding connection lines.

10. The display panel as claimed in claim 9, wherein each of the pixel units comprises a pixel electrode layer, and the shielding connection lines and the pixel electrode layers are arranged at the same layer.

11. The display panel as claimed in claim 10, wherein the array substrate further comprises a plurality of shielding voltage lines parallel to the plurality of data lines, wherein each of the shielding voltage lines is located between two adjacent pixel units; and wherein
the plurality of shielding voltage lines and the shielding connection lines are arranged at the same layer, and two ends of one of the shielding connection lines are respectively electrically connected to two adjacent shielding voltage lines.

12. The display panel as claimed in claim 11, wherein an electrical signal transmitted by the shielding voltage line is a constant-voltage direct-current signal, and the constant-voltage direct-current signal is greater than or equal to 6 volts and less than or equal to 8 volts.

13. The display panel as claimed in claim 10, wherein one of the shielding connection lines comprises a first connection line and a second connection line, the first connection line is parallel to the data lines, and the second connection line is parallel to the scan lines; and
a first end of the first connection line is electrically connected to one of the common electrode layers through a first via hole, and a second end of the first connection line is electrically connected to a first end of the second connection line; and a second end of the second connection line is electrically connected to another one of the common electrode layers through a second via hole.

14. The display panel as claimed in claim 10, wherein each of the common electrode layers comprises a first contact terminal and a second contact terminal, and the common electrode layer is electrically connected to the shielding connection lines on two sides of the common electrode layer respectively by the first contact terminal and the second contact terminal, wherein in the same common electrode layer, the first contact terminal and the second contact terminal are arranged along diagonals of the common electrode layer or arranged along the extending direction of the data lines.

15. The display panel as claimed in claim 10, wherein in a direction of a top view of the array substrate, an orthographic projection of one of the pixel electrode layers is located within an orthographic projection of one of the common electrode layers; and the common electrode layers and the scan lines are arranged at the same layer.

16. The display panel as claimed in claim 10, wherein in the same pixel unit, a storage capacitor is formed between the common electrode layer and the pixel electrode layer.

17. A display terminal, comprising a terminal body and a display panel, wherein the terminal body and the display panel are combined into a whole, and the display panel comprises an array substrate and a color film substrate, wherein the color film substrate and the array substrate are arranged opposite to each other, and the array substrate comprises a plurality of scan lines and a plurality of data lines intersecting with the plurality of scan lines, wherein a plurality of pixel units are defined by the plurality of scan lines and the plurality of data lines; and each of the pixel units comprises a common electrode layer; and wherein
the array substrate further comprises a plurality of shielding connection lines, wherein in an extending direction of the data lines, the common electrode layers in two adjacent pixel units are electrically connected by one of the shielding connection lines.

18. The display terminal as claimed in claim 17, wherein each of the pixel units comprises a pixel electrode layer, and the shielding connection lines and the pixel electrode layers are arranged at the same layer.

19. The display terminal as claimed in claim 18, wherein the array substrate further comprises a plurality of shielding voltage lines parallel to the plurality of data lines, wherein each of the shielding voltage lines is located between two adjacent pixel units; and wherein
the plurality of shielding voltage lines and the shielding connection lines are arranged at the same layer, and two ends of one of the shielding connection lines are respectively electrically connected to two adjacent shielding voltage lines.

20. The display terminal as claimed in claim 19, wherein an electrical signal transmitted by the shielding voltage line is a constant-voltage direct-current signal, and the constant-voltage direct-current signal is greater than or equal to 6 volts and less than or equal to 8 volts.
